(19) United States
(12) Patent Application Publication
(10) Pub. No.: US 2024/0094278 A1
(43) Pub. Date: Mar. 21, 2024

(54) APPARATUS AND METHOD OF INCREASING PRECISION CONTROL OF CHARGE DEPOSITION ONTO A SEMICONDUCTOR WAFER SUBSTRATE

(71) Applicant: FemtoMetrix, Inc., Los Angeles, CA (US)

(72) Inventors: Anatoly A. Shtykov, Irvine, CA (US); Timothy M. Wong, Los Angeles, CA (US)

(21) Appl. No.: 18/350,250

(22) Filed: Jul. 11, 2023

Related U.S. Application Data
(60) Provisional application No. 63/388,400, filed on Jul. 12, 2022.

(51) Int. Cl. G01R 31/265; G01R 31/26

(52) U.S. Cl. CPC G01R 31/265; G01R 31/2601

(57) ABSTRACT

The present invention relates to corona charge deposition systems that use High Voltage (HV) amplifiers for precisely controlling corona charge deposition. Some implementations, provide a corona charge deposition system that uses multiple voltage sources to maintain specified voltages applied on several electrodes to precisely control the corona current required to deposit a desired amount of charge on a sample. The HV amplifiers are able to source and sink currents to maintain stable voltages applied on control electrodes in the presence of a higher voltage applied on a needle electrode. The proposed apparatus and method of monitoring multiple signals, controlling multiple voltages, and predicting charge profile deposited on a sample can precisely control charge deposition processes.

### PRIORITY CLAIM

This application claims the priority benefit of U.S. Patent Prov. App. 63/388,400, entitled APPARATUS AND METHOD OF INCREASING PRECISION CONTROL OF CHARGE DEPOSITION ONTO A SEMICONDUCTOR WAFER SUBSTRATE, filed Jul. 12, 2022, which is incorporated herein by reference in its entirety.

### BACKGROUND

### Field

The present invention is related to the technical field of semiconductor wafer testing, and more particularly, to non-contact, non-invasive methods for testing and characterizing such wafers.

### Description of the Related Art

A Corona Gun (CG) is a tool for depositing charge onto a semiconductor wafer, e.g., when determining the electrical properties of the wafer or interfaces included in the wafer. A corona gun may include both charge dissipating and electrically isolating parts. Controlling charge deposition on a sample (e.g., a semiconductor wafer) by a CG can be a useful feature when characterizing layers and interfaces of a sample.

### SUMMARY

Various methods and systems for precisely and independently controlling multiple high voltage (HV) sources according to some embodiments may include:

Providing High voltage (HV) amplifiers that can source and sink currents and using these HV amplifiers to apply and/or maintain stable voltages to and/or on one or more electrodes of a corona charge deposition system that can be in electrical communication (or be electrically coupled) with each other or other electrodes and/or one or more corona needles (e.g., via corona charge or corona charge flow) where the other electrodes and/or corona needles may receive voltages higher than the stable voltages provided to the one or more electrodes.

Using these HV amplifiers can help to maintain stable and/or regulated output voltage in the presence of external current flowing into the outputs of the HV amplifiers (e.g., from the one or more electrodes connected to the HV amplifiers). Additionally use of these HV amplifiers can enable production of precisely controlled output voltages independent of a direction of electric current flow at the output port of the HV amplifier (into the output port or out of the output port).

The apparatus may monitor and record the charging process in real time while monitoring one or more real time voltages, currents or charge signals and may independently adjust and control one or more output voltages (e.g., high voltage outputs) applied onto one or more electrodes and/or needles of a corona charge deposition system, to deposit a specified amount of charge on a wafer with high precision.

Improving the precision and stability of voltages provided to the electrodes of a multi-electrode precision corona charge deposition system, can improve the flexibility of the system (e.g., maintaining stable voltages in the presence of unpredictable electrical interference), facilitate temporal control over charge deposition on a sample, and provide estimated charge deposition levels that may be used to determine properties of samples/materials, especially in time-critical applications.

In some implementations, the apparatus may use a microcontroller to implement a closed-loop control of the charge deposition. The microcontroller can monitor a corona current in real time and during charge deposition and can control (e.g., turn off) the voltage provided to one or more electrodes once a specified dose is deposited on a sample (e.g., a wafer).

Using a microcontroller with a closed loop manager, allows for the control of a needle voltage (e.g., provided to a corona needle or emitter electrode) to maintain a constant or nearly or substantially constant or more constant corona current (e.g., corona charge flow) which results in increased charge profile repeatability.

Three-dimensional (3D) printing technology may be used to fabricate corona gun components having precise geometries, dimensions and/or material properties. For example, 3D printing technology may be used to fabricate a housing for the corona gun. Using 3D printing may allow for material variation for separate parts of the holder.

Since the corona gun components are exposed to high level of voltages and charge densities, such components may be fabricated using materials having high dielectric constants and other electrical and material characteristic that may improve the performance of the corona gun. For example, components for holding a corona electrode can be fabricated from 3D printed material having a high dielectric constant to provide electrical isolation.

As another example, 3D printable materials used to fabricate components surrounding (or in the vicinity) of the corona gun mask may be selected from charge dissipative materials or static-dissipative materials to dissipate charge and reduce or minimize excess charge accumulation on those components (that may influence corona generation and direction).

In one aspect, an apparatus for providing semiconductor wafer surface corona charging, includes: one or more High Voltage (HV) amplifier systems that can source and sink currents while maintaining a stable voltage, in the presence of a higher voltage external source in electrical contact with the HV amplifier. The higher voltage supplies the voltage to a corona needle to generate positive and negative corona charge, and an electrode in electrical contact with lower voltage sources configured are to focus the corona charge.

In another aspect, a corona charge deposition system is configured to dispose electric charge on a sample via corona charge flow, the corona charge deposition system includes: at least one emitter electrode provided with a first voltage, the said at least one emitter electrode configured to generate the corona charge; at least one control electrode disposed downstream said at least one emitter electrode such that said control electrode is closer to the sample than said at least one emitter electrode, the said control electrode provided with a second voltage lower than the first voltage and configured to control the corona charge flow; at least one high voltage (HV) amplifier configured to generate the second voltage. The at least one HV amplifier is configured to generate and provide a source current to the at least one control electrode and sink an external current received from the at least one control electrode while keeping the second voltage within a specified range.

In another aspect, a corona gun includes: a needle holder comprising a three dimensionally (3D) printed disk; and a focus ring comprising a 3D printed shell with a central open region. The focus ring is attached to a needle holder and an emitter electrode attached to the needle holder. The needle holder is configured to electrically isolate the emitter electrode from the focus ring.

In another aspect, a method of fabricating a corona gun includes: three dimensionally printing an needle holder configured to hold a needle electrode; three dimensionally printing a cylindrical shell having an open central region on the needle holder. The needle holder is configured to electrically isolate the needle electrode from the cylindrical shell.

In another aspect, a method of fabricating a corona gun includes: three dimensionally printing a needle holder configured to hold a needle electrode; fabricating a cylindrical shell having an open central region on the needle holder; wherein the needle holder is configured to electrically isolate the needle electrode from the cylindrical shell.

### BRIEF DESCRIPTION OF THE DRAWINGS

The figures diagrammatically illustrate aspects of various embodiments of different inventive variations.

FIG. 1 is a block diagram of an example push-pull HV amplifier system that may be used to generate and control voltages for electrodes and corona needles of a corona gun.

FIG. 2 is a block diagram of a corona charge deposition system with real-time data acquisition and monitoring (referred to as a data acquisition corona gun (DAQ CG) Charging System).

FIG. 3 is a diagram illustrating an example of a corona gun comprising a needle holder, a focus ring, a mask holder, a mask, and the surrounding parts. The components of the corona gun may be 3D printed in various implementations.

### DETAILED DESCRIPTION

Precise control of the charge deposition on a sample (e.g., a semiconductor wafer) may be a useful feature in many applications including but not being limited to characterizing semiconductor layers and interfaces and other applied material applications.

In some cases, to accurately deposit corona charge on a sample (e.g., a surface of semiconductor wafer), multiple electrodes of the corona gun may be biased at different levels of High Voltage (HV). In some examples, electrodes of a corona gun may include a needle electrode that generates the corona charge, a focus ring and a mask that control the spatial distribution of the corona charge. In some examples, the needle electrode may generate a corona charge flow toward the sample and the focus ring and/or the mask may control the spatial distribution of the corona charge flow and thereby the corona charge disposed on the sample.

Controlling multiple voltage levels (e.g., high voltage levels applied on multiple electrodes of a corona charge deposition system), may involve the use of multiple independent precision voltage sources. As such, a corona charge deposition system may use multiple voltage sources to maintain specified voltages applied on electrodes to precisely control the corona current require to deposit a desired amount of charge on a sample.

In some cases, using precision HV sources that cannot handle current flowing into the output (load terminated to a higher voltage) can lead to unstable and unpredictable voltage on their output.

Some corona charge deposition systems provide process-adaptable charge deposition using closed-loop operation.

Additionally, closed loop control of charge deposition on a wafer may be beneficial since the charge deposition rate depends not only on the voltage magnitude of the voltages applied on the electrodes, but also on the condition of the environment surrounding the wafer, the amount of charge on the wafer (e.g., already deposited on the wafer), and charging or discharging of corona gun parts or any combination of these.

The proposed apparatus and methods can be used to monitor multiple signals, control multiple voltages, and predict charge profile deposited on a sample for precisely controlling charge the deposition process.

In some cases, 3D printing of one or more corona gun parts may provide precise control over geometry and material properties of the parts and thereby reduce or minimize variations (e.g., variation in dimension, geometry and possibly material properties) in different corona gun parts, increase or maximize charge dissipation via some corona gun parts, and/or improve electrical isolation for some corona gun parts.

### Corona Charge Deposition Control System

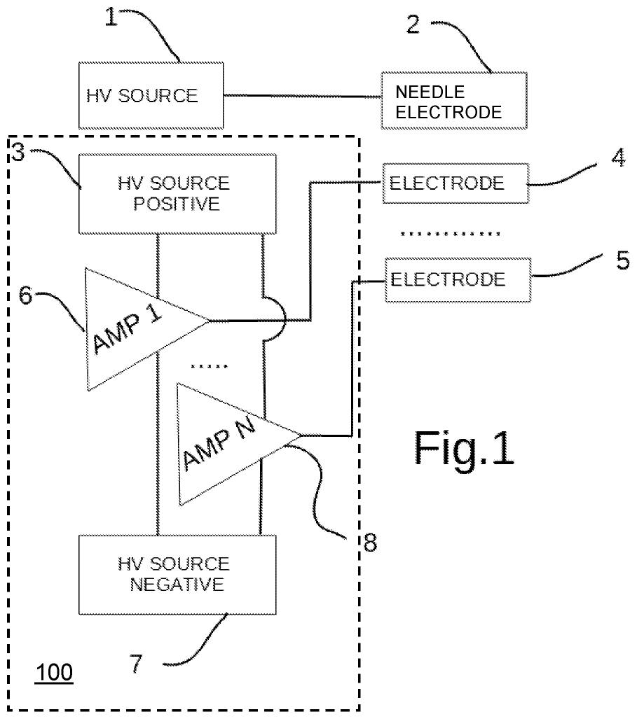

FIG. 1 is a block diagram of an example apparatus 100 configured to supply voltages and currents to one or more control electrodes (e.g., electrodes 4, 5) of a corona gun. In some examples, the corona gun may include at least one needle electrode 2 (also referred to as a corona needle or emitter electrode). The needle electrode 2 may be configured to generate the corona charge or corona charge flow (e.g., an ion beam) and the control electrodes 4, 5 may be configured to control a spatial distribution of the corona charge or corona charge flow (e.g., by focusing the corresponding ion beam). In some implementations, apparatus 100 may comprise the needle electrode 2 and the control electrodes 4, 5. A high voltage external source 1 may supply a needle voltage to the needle electrode 2, to generate positive or negative corona charge on a sample. In some cases, a control electrode may comprise a focus ring, a section of the focus ring, or a conductive mask. The needle electrode, focus ring, and the mask can be components (e.g., integrated components) of a corona gun.

In some cases, the needle electrode 2 and the control electrodes 4, 5 may electrically interfere with each other or be affecting each other via the corona current. In some cases, the needle (or emitter) electrode 2 can be electrically coupled to the least one control electrode via the corona charge flow. For example, when a voltage supplied to the needle electrode 2 is larger than a voltage supplied to the control electrodes 4, 5, a current (e.g., an external current) flows into the voltage sources and/or amplifiers that supply voltages to the control electrodes 4, 5. In some cases, when a voltage source and/or amplifier cannot sink current, the external current follows changes the voltage supplied by such voltage source and/or amplifier resulting in a change of the amount and/or distribution of charge deposited on the sample.

The apparatus 100 may include one or more HV amplifiers 6, 8 that receive electrical inputs from at least two high voltage sources 3, 7 and supply voltages to one or more control electrodes 4, 5. In some implementations, at least, two high voltage sources 3, 7 may comprise positive and negative voltage sources or outputs of at least one voltage source. In some cases, the one or more HV amplifiers 6, 8 may source and sink electric currents while maintaining a stable voltage supplied to the one or more control electrodes 4, 5 when the corona needle 2 is connected to a high voltage external source 1 and generates positive and negative corona charge on the sample. The HV amplifiers 6, 8 are in electrical contact with the control electrodes 4, 5 and supply voltages to the control electrodes 4, 5. In some cases, magnitudes of voltages supplied to the control electrodes 4, 5 is lower than the magnitude of the voltage supplied to the needle electrode 2.

In some cases, the control electrodes 4, 5 may be configured to focus the corresponding corona charge (or corona charge flow) on the sample. In some cases, the control electrodes 4, 5 can be used to focus, shape, and mask an ion beam generated by the needle electrode 2. The needle electrode 2 may be supplied with a high voltage to generate and/or maintain the corona charge (e.g., corona charge flow, or charge density or ion flux of the corresponding ion beam) at a specified level (e.g., a calculated level).

In some cases, the one or more HV amplifiers 6, 8 may maintain the voltage supplied to the one or more control electrodes within a specified range. For example, the amplifiers 6, 8 can output well-controlled voltages in the range of hundreds of volts while maintaining stability and repeatability of an output voltage within few volts or few millivolts from a target voltage by sourcing or sinking the external currents that may be received via the control electrodes 4, 5.

The HV amplifiers 6, 8 may be powered by a first HV source 3 (e.g., providing a positive voltage) and a second HV source (e.g., providing a negative voltage). In some cases, the positive and negative voltages provided to the HV amplifies 6, 8 may be generated by a single HV source and supplied via two separate outputs of the single HV source. In some cases, the impact of interference and/or cross-talk between the control electrodes 4, 5 and the needle electrode 2 on the HV amplifiers 6, 8, can be compensated using push-pull mechanisms. In some examples, the output of the HV amplifiers 6, 8 may comprise push-pull outputs that maintain the voltages supplied to the control electrodes 4, 5 even when these electrodes 4, 5 are kept at lower voltages compared to a voltage supplied to the needle electrode 2. In some cases, the level of voltage provided by the HV source 1 may be larger than that of the HV source 3 and HV source 4. In some examples, the voltage supplied to the needle electrode 2, to produce corona discharge (e.g., the corona charge flow), may be in kilovolt (KV) range, e.g., from 1 KV to 3 KV, from 3 KV to 6 KV, form 6 KV to 10 KV, any range formed by any of these values or may be outside these ranges. The voltage supplied to a control electrode may be less than 1 KV, e.g., from 100 V to 300 V, from 300 KV to 500 KV, from 500 V to 900 KV, or any range formed by any of these values or may be outside these ranges.

With continued reference to FIG. 1, when HV sources that cannot handle current flowing into their output ports (e.g., load terminated to a higher voltage), are used to supply voltage to the control electrode 4, 5, the voltages applied on the control electrodes 4, 5, may become unstable and unpredictable.

A specified amount of charge can be generated on a substrate by supplying stable, precise, and independently controlled voltages to different electrodes of the corona charge deposition system. As mentioned above, when the voltage sources that drive the control electrodes 4, 5 cannot sink external currents, for example, if they are terminated to a signal common level or to a lower voltage level (e.g., compared to a voltage applied on a an interfering electrode), the voltage provided by such sources changes when an external current (e.g., residual current generated due interference with needle electrode) flows into their outputs. As a result, the parameters of ion beams generated and controlled based on a voltage provided by such voltage sources may change and the corresponding charge deposited on a sample may not have a desired or specified amount of charge and/or charge distribution shape/profile. Generally, instability of voltages provided to the needle electrode, and/or the control electrodes can affect the charge deposition process and the amount of charge deposited on a sample.

With continued reference to FIG. 1, the HV amplifiers 6, 8 included between the HV sources 3, 7 and the control electrodes 4, 5 may be configured to handle current sourcing/sinking conditions and thereby maintain the levels of voltages provided to the control electrodes 4 at specified levels, e.g., by compensating the impact of electrical interference between electrodes and/or presence of external charge flowing toward the output of the HV amplifiers 6, 8 (e.g., when the voltage supplied to the needle electrode 2 is higher than the voltages supplied to the control electrodes 4, 5).

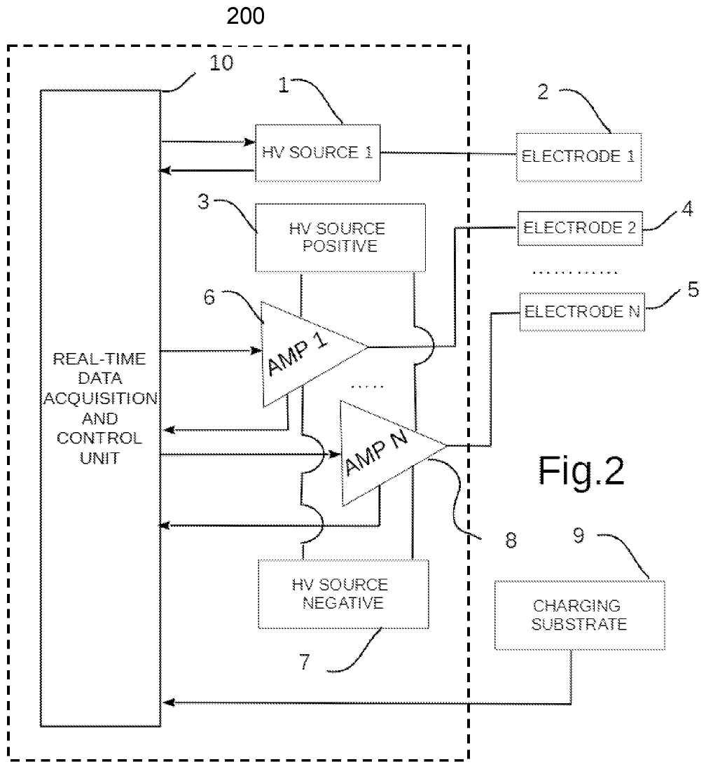

FIG. 2 is a block diagram of another example apparatus 200 or voltage supply system for corona charge deposition. In some cases, the apparatus 200 may be included in a corona charge deposition system. In some examples, the apparatus 200 may comprise one or more features of the apparatus 100 described above with respect to FIG. 1. In some implementations, at least one of the high voltage sources that supply voltage to the electrodes of the corresponding corona charge deposition system can be an external source not included in the apparatus 200. In some cases, the apparatus 200 may comprise the apparatus 100, the high voltage source 1, and a real-time data acquisition (DAQ) and control electronics 10. In some implementations, the apparatus 200 may comprise the needle electrode 2 and the control electrodes 4, 5. In some other implementations, the apparatus 200 may comprise two or more output ports configured to be electrically connected to one or more electrodes of a corona gun (e.g., via electric cables). In some examples, the apparatus 200 may include at least one input port configured to receive a current and/or voltage from a substrate on which charge is deposited under the control of the apparatus 200. The real-time data acquisition (DAQ) and control electronics 10 may be in two-way (bidirectional) communication (e.g. electrical communication) at least with the HV amplifiers 6, 8 that are powered by two HV voltage sources 3, 7. Additionally, the real-time data acquisition (DAQ) and control electronics 10 may be in two-way electrical communication with the HV source 1 that supply voltage to the needle electrode 2. In some examples, a two-way communication can be established via a bidirectional communication link (e.g., a bidirectional wired or wireless electrical communication link, or a bidirectional optical link). In some cases, the HV amplifiers 6, 8 can source and sink electric currents while maintaining a stable voltage on the control electrodes 4, 5 in the presence of electrical interference between the control electrodes 4, 5 and the needle electrode 2 that is driven by HV source 1 having a higher voltage than the voltages applied on the control electrodes 4, 5. In some implementations, the real-time data acquisition and control electronics 10 can be in two-way electrical communication with the HV source 3 and/or HV source 7, or an HV source that supplies positive and negative voltages to the HV amplifiers 6, 7. In some cases, the voltage levels generated by the HV source 3 and HV source 7 may be lower than that of the HV source 1. In some examples, the real-time data acquisition and control electronics 10 can be in electrical contact with the charging substrate 9 (e.g., a wafer on which charge is disposed) and receive a feedback signal (e.g., an electric current) from the substrate to control the HV source 1 and HV amplifiers 6, 8. In particular, the acquisition and control electronics 10 may use the magnitude and/or direction of an electric current flowing between the acquisition and control electronics 10, and the charging substrate 9 as a feedback to control the HV amplifiers 6, 7, and or the HV voltage source 1. In some implementations, the electrical contact between the real-time data acquisition and control electronics 10, and the charging substrate 9, may comprise a conductive chuck on which the substrate is mounted. Additionally or alternatively, a feedback signal may comprise magnitude of: the electric current flowing into the needle electrode 2, the voltage supplied to the needle electrode 2, the voltage supplied to one or both control electrodes 4, 5, and/or the current flowing to one or both of the control electrodes 4, 5.

In some cases, a current flow between the chuck or the charging substrate 9 and the real-time data acquisition and control electronics 10, may indicate an amount of charge deposited on the charging substrate 9 and/or a rate of charge deposition on the charging substrate 9. In some cases, the real-time data acquisition and control electronics 10, may determine and monitor the charge deposition (e.g., an amount of charge deposited or a rate of charge deposition) based on a current flow to the corona needle 2, and/or a current flow between the charging substrate 9 (or the mounting chuck in electric contact with the charging substrate) and the real-time data acquisition and control electronics 10.

In some embodiments, the real-time data acquisition and control electronics 10 may comprise a microcontroller configured to control the charge deposition process using a closed-loop control mechanism. The microcontroller may monitor the feedback signal (e.g., corona current) received from the charging substrate 9 in real time and control the charge deposition process (e.g., by controlling the HV source(s) 1 and HV amplifiers 6, 8) based at least in part on the feedback signal. For example, the microcontroller may turn off one or more voltage sources when the feedback signal indicates that the required dose of charge is disposed on the sample (e.g., wafer).

In some cases, controlling the HV source 1 using a closed loop control mechanism implemented by the microcontroller of the real-time data acquisition and control electronics 10, may allow controlling the current and/or voltage supplied to the needle electrode 2 for increased charge profile repeatability. In some cases, the closed loop control may improve the corona charging process (e.g., making the charge profile more repeatable) by maintaining a constant and stable corona current supply to the needle electrode 2 and thereby to the ion beam.

In some implementations, providing increase or possibly full control over the needle voltage supplied to the corona needle together with increasing the reliability of focus, shape, and mask voltages allows for creating different charge deposition recipes for different type of the substrates. Furthermore, having in process deposition feedback from the substrate 9, allows for depositing a precise amount of charge and may potentially assist in detecting “fault” conditions when the corona deposition is not occurring as predicted or desired.

### 3D Printed Corona Gun Components

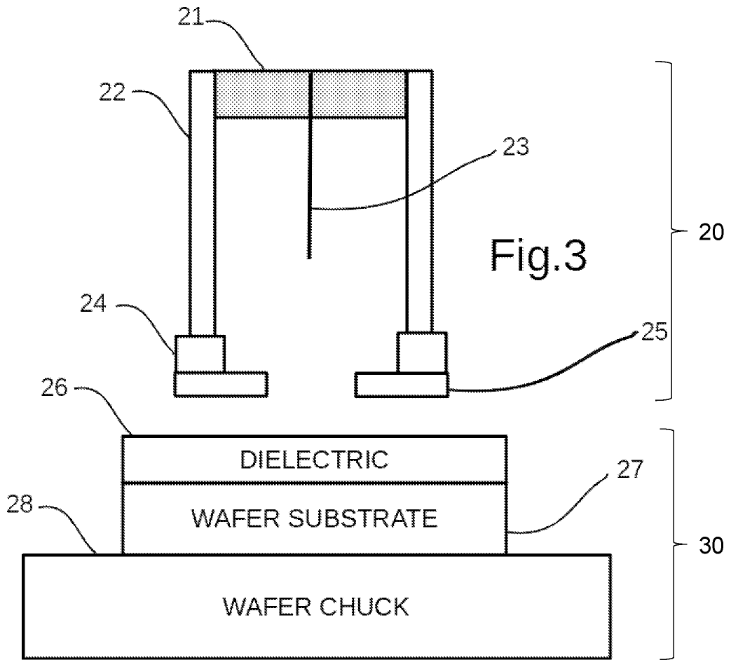

FIG. 3 illustrates a corona gun 20 positioned above a sample. The sample 30 may comprise a wafer substrate 27 (e.g., comprising semiconductor), having a dielectric layer 26. The wafer substrate 27 may be disposed on a wafer chuck 28. The corona gun 20 may comprise an upper portion or a needle holder 21 configured to hold the corona needle 23 in a stationary state, a focus ring 22 configured to control the ion beam originated from the corona needle 23, a mask holder 24, and a conductive mask 25 (e.g., a metal mask). In some cases, the needle holder 21 may comprise a high-k dielectric material, the focus ring 22 may comprise a metal or conductive material, and the mask holder 24 may comprise a highly dissipative material (e.g., a static dissipative plastic or polymer), which also electrically isolates the focus ring 22 from the mask 25. In some examples, the mask 25 may be attached to the mask holder 24 using a conductive glue to provide electrical connection between the mask 25 and the mask holder 24. In some other examples, the mask 25 may be mechanically attached and electrically connected to the mask holder 24 without using any glue.

In some examples, the needle holder 21 may comprise a disk. The diameter of the disk shaped needle holder 21 can be from 5 to 10 mm, or from 10 mm to 15 mm, from 15 to 20 mm, from 20 m to 25 mm, or from 25 to 30 mm or any range formed by any of these values or may be outside these ranges. In some implementations, the diameter of the needle holder 21 may be designed so that an optical path of a laser beam incident on the sample 30 (e.g., incident on the dielectric layer 26) can be cleared by a small displacement of the corona gun 20 away from a point of incidence. The focus ring 22 may comprise a cylindrical shell. In some cases, the cylindrical shell may have a wall thickness from 1 to 2 mmm, from 2 to 3 mm, from 3 to 4 mm, and an inner diameter substantially equal to the diameter of the needle holder (e.g., 6-30 mm). The cylindrical shell may have a height from 10 to 20 mm, from 20 to 30 mm, from 30 mm to 40 mm. The internal and/or the external surfaces of the cylindrical shell may comprise polished and smooth surfaces.

In some examples, at least one of the components of the corona gun 20 and/or many or most of the components thereof may be fabricated via an additive manufacturing process such as using 3D printing. In some examples, at least one component of the corona gun may be fabricated separately, e.g., using 3D printing and may be attached to another component of the corona gun. In some cases, most of components of the corona gun are fabricated via an additive manufacturing process such as using 3D printing. In some cases, most of or the entire corona gun may be fabricated via an additive manufacturing process such as using 3D printing. In some cases, one component of the corona gun 20 may be 3D printed on another component (e.g., a 3D printed component) of the corona gun 20. In some cases, at least one component of the coronal gun 20 may be fabricated using subtractive manufacturing (e.g., by trimming and machining). In some implementations, the focus ring 22 may be fabricated using machining, while the needle holder 21 and the mask holder 24 are 3D printed. In some examples, the focus ring 22 may be fabricated using 3D printing and then mechanically trimmed (e.g., polished) to provide a smooth internal surface. In some cases, the needle holder 21 may comprise a 3D printed high-k dielectric (e.g., having a dielectric constant from 3 to 5), the focus ring 22 may comprise a 3D printed metal, and the mask holder 24 may comprise a 3D printed dissipative material. In various implementations, the needle holder 21 may comprise Ultem 9085, PEEK, or Derlin. The mask holder may comprise an electrostatic discharge material (ESD) such as a carbon filled plastic having a surface resistance from 10⁵ to 10¹¹ ohm-cm. In these implementations, the needle holder 21 and/or the mask holder 24 may be 3D printed on the focus ring 22, or the corona gun 20 may be assembled after fabrication of individual components.

The corona gun can be positioned at a predetermined working distance above sample which may comprise a semiconductor wafer. In some cases, the sample comprises a semiconductor substrate 27 having the dielectric 26, which is either deposited or produced through oxidation on the underlying semiconductor substrate 27. The semiconductor wafer or semiconductor substrate 27 is positioned on top of the substrate chuck 28.

3D printing, or as commonly referred to as additive manufacturing of parts of the corona gun allows for precise control of the part geometry as well as the part material properties. To achieve precise geometry and material properties in corona gun components, 3D printing technology is used to create several parts for the corona gun. Given that the needle holder 21 provides electrical isolation between the corona needle 23 and the focus ring 22, the 3D printed material used for fabricating the needle holder 21 may have high dielectric constant to provide the electrical isolation, e.g., when the corona needle 23 is kept at a different, e.g., higher, voltage compared to the focus ring 22. In some cases, the material (e.g. 3D printed material) used for fabricating the mask holder 24 may provide a high level of charge dissipation to reduce or minimize its influence on corona charge generation and direction. In some cases, the mask holder 25 may comprise a 3D printable material that is static-dissipative and allows charge to dissipate.

In some implementations, the metal mask 25 can be 3D printed using a metal or another conductive material and/or charge dissipative material. The metal mask 25 may comprise an aperture configured to block a portion of corona charge flowing toward the sample and tailor the size and/or shape (e.g., a cross-sectional shape and size) of the corona charge flow (e.g., an ion beam) incident on the sample such as on the semiconductor wafer (e.g., the dielectric layer 26 on the semiconductor substrate 27) and thereby the shape and size of a charged region on sample such as on the semiconductor wafer (e.g. the dielectric layer 26 on the semiconductor substrate 27). In some cases, the aperture may have a conical shape. In some examples, the aperture may be configured to reduce interference with one or more light beams used to optically interrogate the sample (e.g., a layer or an interface in the sample).

### Conclusion

The advantages of the disclosed systems and methods include, without limitation, a configuration for precisely controlling voltages and currents supplied to one or more electrodes of a corona gun to focus and/or control corona charge in the presence of interference and crosstalk between electrodes provided with significantly different voltages and currents. For example, when the system supplies a high voltage to a corona needle (also referred to as emitter electrode or needle electrode) and a lower voltage to one or more control electrodes in the vicinity of the corona needle. Additionally, some designs may provide precise control of corona charge concentration through real-time data acquisition and control of corona charge generation and shaping by controlling voltages and currents provided to the corresponding electrodes through feedback control. In some cases, the feedback control may comprise closed-loop feedback control. In some implementations, the feedback control may comprise controlling the voltages and/or currents provided to the one or more electrodes (e.g., control electrodes or needle electrodes) of a corona gun using one or more feedback signals indicative of the characteristics of a corona charge (e.g., ion beam) generated by the system, an amount of charge disposed on the sample, and/or a rate of charge deposition on the sample. In some cases, a feedback signal may comprise a sample current received from a charging substrate, a magnitude of voltage applied on the needle electrode, a magnitude of current flowing into the needle electrode, a magnitude of voltage applied on at least one control electrode, and/or a magnitude of current flowing into the at least one control electrode.

Advantageously, some embodiments of the present disclosure may provide 3D printed corona gun parts, and/or 3D printed corona guns. In some cases, 3D printing allows precise control over the dimensions, geometry and/or material properties of corona gun parts. In some examples, 3D printing may allow fabrication of corona needle holders comprising high-k dielectric materials and/or corona mask holders comprising charge dissipative material.

The disclosed systems are configured to precisely control corona charge deposition, for example, in the context of semiconductor wafer testing. More specifically, the disclosed systems are configured to improve and facilitate charge deposition for non-contact, non-invasive testing and characterization of semiconductor wafers. Such corona guns may be included inline a semiconductor fabrication process line.

In various implementations, the corona gun is used in conjunction with an optical metrology system such as second harmonic generation metrology system. As discussed in the U.S. Patent Publication No. 2015/0330909 titled “WAFER METROLOGY TECHNOLOGIES” published on Jan. 17, 2018, which is incorporated herein by reference in its entirety, for example, second harmonic generation may be employed to obtain information regarding properties of a sample such as a silicon wafer. A metrology system for obtaining measurements of the sample may include a laser that outputs light that is directed onto the sample and an optical detector that receives light reflected from the sample. This light reflected from the sample may comprise a second harmonic generation signal that can be analyzed with electronics to obtain information regarding the sample.

In some implementations, the metrology system may further comprise a corona gun, for example, such as discussed herein, to deposit charge on the sample. The second harmonic generation signal reflected from the sample may be affected by the presence of charge deposited by the corona gun. Likewise, SHG measurements can be obtained with charge deposited on the sample by the corona gun to provide information regarding the sample. Discussion of use of a corona gun in a metrology system configured to measure second harmonic generation is discussed in U.S. Patent Publication No. 2020/0057104 titled “FIELD-BIASED NONLINEAR OPTICAL METROLOGY USING CORONA DISCHARGE SOURCE” which published on Feb. 20, 2020, which is which is incorporated herein by reference in its entirety. As discussed herein, the second harmonic generation metrology system may be included inline a semiconductor chip fabrication processing line.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention.

### EXAMPLE EMBODIMENTS

Example embodiments described herein have several features, no single one of which is indispensable or solely responsible for their desirable attributes. A variety of example systems and methods are provided below.

### Group 1

Example 1: An apparatus to provide semiconductor wafer surface corona charging, comprising: one or more High Voltage (HV) amplifier systems that can source and sink currents while maintaining a stable voltage, in the presence of a higher voltage external source in electrical contact with the HV amplifier, the higher voltage supplying the voltage to a corona needle to generate positive and negative corona charge, and the presence and electrical contact with lower voltage sources configured to focus the corona charge.

Example 2: The apparatus according to Example 1, wherein said HV amplifier voltages are applied to one or more electrodes to provide control for precision charge deposition.

Example 3: The apparatus according to Example 1, wherein said higher voltage is applied to the corona needle and can produce currents that are injected onto said HV amplifiers from the ranges outside of the lower HV amplifier rails.

Example 4: The apparatus according to Example 3, wherein higher voltage interference to currents being drawn by the HV amplifier is compensated using push-pull outputs that are able to source or sink current while keeping the voltage as required.

Example 5: The apparatus according to Example 4, wherein compensated push-pull outputs allow lower HV amplifiers to maintain the required voltages.

Example 6: An apparatus and method to predict and realize precision charge deposition comprising: monitoring the resultant corona charge flow; monitoring one or more signals from registered currents and voltages from the electrodes; adjusting applied voltages, currents and process deposition time to compensate deviations from intended charge deposition concentration.

Example 7: The apparatus according to Example 6, wherein a real-time data acquisition and control electronics is used to monitor one or more High Voltage (HV) amplifier system voltages.

Example 8: The apparatus according to Example 6, wherein a real-time data acquisition and control electronics is used to produce higher voltage supplying the voltage required at a corona needle to generate positive and negative corona charge.

Example 9: The apparatus according to Example 6, wherein a real-time data acquisition and control electronics is used to monitor corona deposition based current flowing into the corona needle and the second resultant current flowing into the wafer chuck-based return electrode.

Example 10: A method for 3D printing of a first type of printed material and 3D printing of a second type of material, the method comprising: a first type of printable material for the corona gun body or housing that holds a corona gun mask using a 3D printable material which is charge dissipative; and a second type of printable material for holding the needle for the focus cylinder using a material that has a high dielectric constant to provide electrical isolation.

Example 11: A method for printing a 3D removable mask comprising: a printable material that is charge dissipative; a printable material that will allow for varying aperture diameter and shape.

Example 12: The method according to Example 11, wherein the aperture shape can be conic, which will provide for reduced interference with an adjacent interrogating light beam.

### Group 2

Example 1. A corona charge deposition system configured to dispose electric charge on a sample via corona charge flow, the system comprising:
at least one emitter electrode provided with a first voltage, the said at least one emitter electrode configured to generate the corona charge;
at least one control electrode disposed downstream said at least one emitter electrode such that said control electrode is closer to the sample than said at least one emitter electrode, the said control electrode provided with a second voltage lower than the first voltage and configured to control the corona charge flow; and
at least one high voltage (HV) amplifier configured to generate the second voltage;
wherein the at least one HV amplifier is configured to generate and provide a source current to the at least one control electrode and sink an external current received from the at least one control electrode while keeping the second voltage within a specified range.

Example 2. The system of Example 1, wherein the at least one emitter electrode is electrically coupled to the least one control electrode via the corona charge.

Example 3. The system of Example 1, further comprising a first high voltage (HV) source configured to generate the first voltage provided to the emitter electrode.

Example 4. The system of Example 1, further comprising a plurality of HV sources configured to supply drive voltages to the at least one HV amplifier.

Example 5. The system of Example 4, wherein the drive voltages comprise a positive drive voltage and a negative drive voltage.

Example 6. The system of Example 1, wherein the at least one HV amplifier comprises a push-pull amplifier.

Example 7. The system of Example 1, wherein the at least one HV amplifier comprises a push-pull circuit to keep the second voltage within a specified range in the presence of the external current.

Example 8. The system of Example 3, further comprising control electronics electrically connected to at least one of the sample, the first HV source, or the least one HV amplifier, and configured to control an amount of charge disposed on the sample and/or a rate of charge deposition.

Example 9. The system of Example 8, wherein the control electronics are configured to control an amount of charge disposed on the sample within □ 1 Picocoulomb from a specified amount of charge.

Example 10. The system of Example 8, wherein the control electronics is electrically connected to the first HV source and controls and/or monitors the first voltage.

Example 11. The system of Example 10, wherein the control electronics is electrically connected to the at least one HV amplifier and controls and/or monitors the second voltage.

Example 12. The system of any of Examples 8 to 11, wherein the control electronics is electrically connected to the at least one HV amplifier and/or the first HV source via at least one bidirectional communication link.

Example 13. The system of Example 1, wherein said at least one control electrode comprises a focus ring.

Example 14. The system of Example 1, wherein said at least one control electrode comprises a tubular electrode downstream a position of said emitter electrode such that charge flows through an open central region of said tubular electrode.

Example 15. The system of Example 1, wherein said at least one control electrode comprises a mask.

Example 16. The system of Example 1, wherein said at least one control electrode comprises a control electrode configured to control a spatial distribution of the corona charge flow.

Example 17. The system of any of Examples 8 to 12, wherein the control electronics controls the first and/or the second voltages based at least in part on at least one feedback signal.

Example 18. The system of Example 17 wherein the control electronics is electrically connected to the sample and the feedback signal comprises at least a sample current received from the sample.

Example 19. The system of Example 18, wherein the sample current is indicative of an amount of charge disposed on the sample.

Example 20. The system of Example 18, wherein the sample current is indicative of a rate of charge deposition on the sample.

Example 21. The system of any of Examples 17 to 20, wherein the feedback signal comprises a magnitude of current flowing into the emitter electrode.

Example 22. The system of any of Examples 17 to 21, wherein the feedback signal comprises a magnitude of current flowing into the at least one control electrode.

Example 23. The system of any of Examples 8 to 11, wherein the control electronics are configured to adjust the first and/or the second voltages to compensate deviation of the amount of charge disposed on the sample from a specified amount of charge.

Example 24. The system of Examples 23, wherein the control electronics are further configured to control a first current provided to the at least one control electrode and a second current provided to the emitter electrode to compensate deviation of the amount of charge disposed on the sample from a specified amount of charge.

Example 25. The system of Examples 10, wherein the control electronics comprise a real-time data acquisition system.

Example 26. A corona gun comprising:
a needle holder comprising a three dimensionally (3D) printed disk; and
a focus ring comprising a 3D printed shell with a central open region, said focus ring attached to a needle holder;
an emitter electrode attached to the needle holder;
wherein the needle holder is configured to electrically isolate the emitter electrode from the focus ring.

Example 27. The corona gun of Example 26, wherein the needle holder comprises a 3D printable dielectric material having a dielectric constant from 3 to 5.

Example 28. The corona gun of Example 26, wherein the focus ring comprises a 3D printable conductive material.

Example 29. The corona gun of Example 26, wherein the emitter electrode comprises a needle having a needle length and a needle diameter, wherein the needle length is larger than the needle diameter by a factor of 25-50, and wherein the needle electrode comprises a conductive material.

Example 30. The corona gun of Example 26, wherein said shell comprises a cylindrical shell.

Example 31. The corona gun of Example 26, further comprising a 3D printed mask holder attached to the shell opposite to the needle holder, wherein the mask holder comprises a 3D printable static-dissipative material.

Example 32. The corona gun of Example 31, further comprising a 3D printed removable mask mounted on the 3D printed mask holder between the removable mask and the focus ring, wherein the mask comprises a conductive material.

Example 33. The corona gun of Example 32, wherein the 3D printed removable mask comprises an aperture in a solid barrier.

Example 34. A method of fabricating a corona gun, the method comprising:
three dimensionally printing a needle holder configured to hold a needle electrode; and
three dimensionally printing a cylindrical shell having an open central region on the needle holder;
wherein the needle holder is configured to electrically isolate the needle electrode from the cylindrical shell.

Example 35. The method of Example 34, further comprising three dimensionally printing a mask holder on the cylindrical shell opposite to the needle holder.

Example 36. The method of Example 35, further comprising three dimensionally printing a mask configured to be mounted on the mask holder.

Example 37. The method of Example 34, wherein the needle holder comprises a 3D printable dielectric material having a dielectric constant from 3 to 5.

Example 38. The method of Example 34, wherein the cylindrical shell comprises a 3D printable conductive material.

Example 39. The method of Example 35, wherein mask holder comprises a 3D printable static-dissipative material.

Example 40. The method of Example 36, wherein the mask comprises a solid barrier having an aperture.

Example 41. The method of Example 34, further comprising polishing an internal surface of the cylindrical shell to make it smooth.

Example 42. A corona gun comprising:
a needle holder comprising a three dimensionally (3D) printed disk; and
a focus ring comprising a shell with a central open region, said focus ring attached to a needle holder; and
an emitter electrode attached to the needle holder;
wherein the needle holder is configured to electrically isolate the emitter electrode from the focus ring.

Example 43. The corona gun of Example 42, wherein the needle holder comprises a 3D printable dielectric material having a dielectric constant from 3 to 5.

Example 44. The corona gun of Example 42, wherein the focus ring comprises metal and has a smooth internal surface.

Example 45. The corona gun of Example 42, wherein the emitter electrode comprises a needle having a needle length and a needle diameter, wherein the needle length is larger than the needle diameter by a factor of 25-50, and wherein the needle electrode comprises a conductive material.

Example 46. The corona gun of Example 42, wherein said shell comprises a cylindrical shell.

Example 47. The corona gun of Example 42, further comprising a 3D printed mask holder attached to the shell opposite to the needle holder, wherein the mask holder comprises a 3D printable static-dissipative material.

Example 48. The corona gun of Example 47, further comprising a 3D printed removable mask mounted on the 3D printed mask holder between the removable mask and the focus ring, wherein the mask comprises a conductive material.

Example 49. The corona gun of Example 48, wherein the 3D printed removable mask comprises an aperture in a solid barrier.

Example 50. A method of fabricating a corona gun, the method comprising:
three dimensionally printing a needle holder configured to hold a needle electrode; and
fabricating a cylindrical shell having an open central region on the needle holder;
wherein the needle holder is configured to electrically isolate the needle electrode from the cylindrical shell.

Example 51. The method of Example 50, further comprising three dimensionally printing a mask holder on the cylindrical shell opposite to the needle holder.

Example 52. The method of Example 51, further comprising three dimensionally printing a mask configured to be mounted on the mask holder.

Example 53. The method of Example 50, wherein the needle holder comprises a 3D printable dielectric material.

Example 54. The method of Example 50, wherein the cylindrical shell comprises a conductive material.

Example 55. The method of Example 51, wherein the mask holder comprises a 3D printable static-dissipative material.

Example 56. The method of Example 52, wherein the mask comprises a solid barrier having an aperture.

Example 57. The method of Example 50, wherein fabricating the cylindrical shell comprises fabricating the cylindrical shell using subtractive manufacturing.

Example 58. The method of Example 57, wherein fabricating the cylindrical shell comprises fabricating the cylindrical shell by machining a metal piece.

Example 59. The method of Example 58, wherein fabricating the cylindrical shell comprises providing a smooth internal surface.

### Terminology

Example invention embodiments, together with details regarding a selection of features have been set forth above. As for other details, these may be appreciated in connection with the above-referenced patents and publications as well as is generally known or appreciated by those with skill in the art. The same may hold true with respect to method-based aspects of the invention in terms of additional acts as commonly or logically employed. Regarding such methods, including methods of manufacture and use, these may be carried out in any order of the events which is logically possible, as well as any recited order of events. Furthermore, where a range of values is provided, it is understood that every intervening value, between the upper and lower limit of that range and any other stated or intervening value in the stated range is encompassed within the invention. Also, it is contemplated that any optional feature of the inventive variations described may be set forth and claimed independently, or in combination with any one or more of the features described herein.

As used herein, a phrase referring to “at least one of” a list of items refers to any combination of those items, including single members. As an example, “at least one of: a, b, or c” is intended to cover: a, b, c, a-b, a-c, b-c, and a-b-c.

Though the invention embodiments have been described in reference to several examples, optionally incorporating various features, they are not to be limited to that which is described or indicated as contemplated with respect to each such variation. Changes may be made to any such invention embodiment described and equivalents (whether recited herein or not included for the sake of some brevity) may be substituted without departing from the true spirit and scope hereof. Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

The various illustrative processes described may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. The processor can be part of a computer system that also has a user interface port that communicates with a user interface, and which receives commands entered by a user, has at least one memory (e.g., hard drive or other comparable storage, and random access memory) that stores electronic information including a program that operates under control of the processor and with communication via the user interface port, and a video output that produces its output via any kind of video output format, e.g., VGA, DVI, HDMI, DisplayPort, or any other form.

A processor may also be implemented as a combination of computing devices, e.g., a combination of a DSP and a microprocessor, a plurality of microprocessors, one or more microprocessors in conjunction with a DSP core, or any other such configuration. These devices may also be used to select values for devices as described herein.

The steps of a method or algorithm described in connection with the embodiments disclosed herein may be embodied directly in hardware, in a software module executed by a processor, or in a combination of the two. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more example embodiments, the functions described may be implemented in hardware, software, firmware, or any combination thereof. If implemented in software, the functions may be stored on, transmitted over or resulting analysis/calculation data output as one or more instructions, code or other information on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. The memory storage can also be rotating magnetic hard disk drives, optical disk drives, or flash memory based storage drives or other such solid state, magnetic, or optical storage devices.

Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Operations as described herein can be carried out on or over a website. The website can be operated on a server computer, or operated locally, e.g., by being downloaded to the client computer, or operated via a server farm. The website can be accessed over a mobile phone or a PDA, or on any other client. The website can use HTML code in any form, e.g., MHTML, or XML, and via any form such as cascading style sheets (“CSS”) or other.

Also, the inventors hereof intend that only those claims which use the words “means for” are to be interpreted under 35 USC 112, sixth paragraph. Moreover, no limitations from the specification are intended to be read into any claims, unless those limitations are expressly included in the claims. The computers described herein may be any kind of computer, either general purpose, or some specific purpose computer such as a workstation. The programs may be written in C, or Java, Brew or any other programming language. The programs may be resident on a storage medium, e.g., magnetic or optical, e.g. the computer hard drive, a removable disk or media such as a memory stick or SD media, or other removable medium. The programs may also be run over a network, for example, with a server or other machine sending signals to the local machine, which allows the local machine to carry out the operations described herein.

It is also noted that all features, elements, components, functions, acts and steps described with respect to any embodiment provided herein are intended to be freely combinable and substitutable with those from any other embodiment. If a certain feature, element, component, function, or step is described with respect to only one embodiment, then it should be understood that that feature, element, component, function, or step can be used with every other embodiment described herein unless explicitly stated otherwise. This paragraph therefore serves as antecedent basis and written support for the introduction of claims, at any time, that combine features, elements, components, functions, and acts or steps from different embodiments, or that substitute features, elements, components, functions, and acts or steps from one embodiment with those of another, even if the following description does not explicitly state, in a particular instance, that such combinations or substitutions are possible. It is explicitly acknowledged that express recitation of every possible combination and substitution is overly burdensome, especially given that the permissibility of each and every such combination and substitution will be readily recognized by those of ordinary skill in the art.

In some instances entities are described herein as being coupled to other entities. It should be understood that the terms “interfit”, “coupled” or “connected” (or any of these forms) may be used interchangeably herein and are generic to the direct coupling of two entities (without any non-negligible, e.g., parasitic, intervening entities) and the indirect coupling of two entities (with one or more non-negligible intervening entities). Where entities are shown as being directly coupled together, or described as coupled together without description of any intervening entity, it should be understood that those entities can be indirectly coupled together as well unless the context clearly dictates otherwise.

Reference to a singular item includes the possibility that there are a plurality of the same items present. More specifically, as used herein and in the appended claims, the singular forms “a,” “an,” “said,” and “the” include plural referents unless specifically stated otherwise. In other words, use of the articles allow for “at least one” of the subject item in the description above as well as the claims below.

It is further noted that the claims may be drafted to exclude any optional element (e.g., elements designated as such by description herein a “typical,” that “can” or “may” be used, etc.). Accordingly, this statement is intended to serve as antecedent basis for use of such exclusive terminology as “solely,” “only” and the like in connection with the recitation of claim elements, or other use of a “negative” claim limitation language. Without the use of such exclusive terminology, the term “comprising” in the claims shall allow for the inclusion of any additional element—irrespective of whether a given number of elements are enumerated in the claim, or the addition of a feature could be regarded as transforming the nature of an element set forth in the claims. Yet, it is contemplated that any such “comprising” term in the claims may be amended to exclusive-type “consisting” language. Also, except as specifically defined herein, all technical and scientific terms used herein are to be given as broad a commonly understood meaning to those skilled in the art as possible while maintaining claim validity.

While the embodiments are susceptible to various modifications and alternative forms, specific examples thereof have been shown in the drawings and are herein described in detail. It should be understood, however, that these embodiments are not to be limited to the particular form disclosed, but to the contrary, these embodiments are to cover all modifications, equivalents, and alternatives falling within the spirit of the disclosure. Furthermore, any features, functions, acts, steps, or elements of the embodiments may be recited in or added to the claims, as well as negative limitations (as referenced above, or otherwise) that define the inventive scope of the claims by features, functions, steps, or elements that are not within that scope. Thus, the breadth of the inventive variations or invention embodiments are not to be limited to the examples provided, but only by the scope of the following claim language.

1. A corona charge deposition system configured to dispose electric charge on a sample via corona charge flow, the system comprising:
at least one emitter electrode provided with a first voltage, said at least one emitter electrode configured to generate the corona charge flow;
at least one control electrode disposed downstream said at least one emitter electrode such that said control electrode is closer to the sample than said at least one emitter electrode, said control electrode provided with a second voltage lower than the first voltage and configured to control the corona charge flow; and
at least one high voltage (HV) amplifier configured to generate the second voltage;
wherein the at least one HV amplifier is configured to generate and provide a source current to the at least one control electrode and sink an external current received from the at least one control electrode while keeping the second voltage within a specified range.

2. The system of claim 1, further comprising a first high voltage (HV) source configured to generate the first voltage provided to the emitter electrode.

3. The system of claim 1, further comprising a plurality of HV sources configured to supply drive voltages to the at least one HV amplifier.

4. The system of claim 1, wherein the at least one HV amplifier comprises a push-pull circuit to keep the second voltage within a specified range in the presence of the external current.

5. The system of claim 2, further comprising control electronics electrically connected to at least one of the sample, the first HV source, or the least one HV amplifier, and configured to control an amount of charge disposed on the sample and/or a rate of charge deposition.

6. The system of claim 5, wherein the control electronics are configured to control an amount of charge disposed on the sample within ±1 Picocoulomb from a specified amount of charge.

7. The system of claim 5, wherein the control electronics is electrically connected to the first HV source and controls and/or monitors the first voltage.

8. The system of claim 7, wherein the control electronics is electrically connected to the at least one HV amplifier and controls and/or monitors the second voltage.

9. The system of claim 1, wherein said at least one control electrode comprises a control electrode configured to control a spatial distribution of the corona charge flow.

10. The system of claim 5, wherein the control electronics controls the first and/or the second voltages based at least in part on at least one feedback signal.

11. The system of claim 10 wherein the control electronics is electrically connected to the sample and the feedback signal comprises at least a sample current received from the sample.

12. The system of claim 10, wherein the feedback signal comprises a magnitude of current flowing into the emitter electrode.

13. The system of claim 10, wherein the feedback signal comprises a magnitude of current flowing into the at least one control electrode.

14. The system of claim 5, wherein the control electronics are configured to adjust the first and/or the second voltages to compensate deviation of the amount of charge disposed on the sample from a specified amount of charge.

15. The system of claim 14, wherein the control electronics are further configured to control a first current provided to the at least one control electrode and a second current provided to the emitter electrode to compensate deviation of the amount of charge disposed on the sample from a specified amount of charge.
